(19) United States
(12) Patent Application Publication
(10) Pub. No.: US 2001/0021566 A1
(43) Pub. Date: Sep. 13, 2001

(54) ANODIC OXIDIZATION METHODS

(76) Inventors: HONGYONG ZHANG, KANAGAWA (JP); HIDEKI UOCHI, KANAGAWA (JP); YOSUKE TSUKAMOTO, KANAGAWA (JP); YUTAKA TAKAFUJI, NARA (JP); YASUSHI KUBOTA, NARA (JP)

Correspondence Address: COOK MCFARRON AND MANZO LTD, 200 WEST ADAMS STREET, SUITE 2850, CHICAGO, IL, 60606

(21) Appl. No.: 09/175,844

(22) Filed: Oct. 20, 1998

(30) Foreign Application Priority Data
Oct. 22, 1997 (JP) 9-290138

(51) Int. Cl. H01L 21/76

(52) U.S. Cl. 438/408

(57) ABSTRACT

In an anodic oxidization method of the invention for anodizing areas including and surrounding a plurality of gate electrodes connected to a current supply line by respective gate connecting lines, the current supply line supplies currents to the gate electrodes in a manner that the densities of anodizing currents flowing through corresponding parts of any two parallel-running neighboring gate electrodes arranged in a semiconductor island area become substantially equal to each other. No leakage current flows from one gate electrode to another because the anodizing currents are supplied in such a way that no potential difference occurs between any two neighboring gate electrodes during anodic oxidization as a result of differences in current path length. This makes it possible to prevent crystal defects and partial anodization imperfections which could potentially be caused by leakage currents.

### FIELD OF THE INVENTION

The present invention relates generally to anodic oxidization methods and, more particularly, to anodic oxidization methods which can be advantageously used for anodizing gate electrodes of thin-film transistors (TFTs).

### BACKGROUND OF THE INVENTION

TFTs whose gate electrodes are formed of aluminum and covered with an anodic oxide film are well known in the prior art. In a typical anodic oxidization method, an electrolytic solution 2 is filled in a vessel 1 and TFT gate electrodes and gate connecting lines 4 formed on a substrate 3 are electrically connected with each other and to a current supply line as shown in FIG. 4. The substrate 3 and an electrode plate 5 formed of platinum, for instance, are placed face to face with each other in the electrolytic solution 2 and a power source 6 is connected such that a positive voltage is applied to the current supply line connected to the substrate 3 while a negative voltage is applied to the electrode plate 5. With this arrangement, a current supplied from the power source 6 flows through the gate electrodes and the gate connecting lines 4 and across the electrolytic solution 2, and then to the electrode plate 5. As a result, surfaces of the gate electrodes and the gate connecting lines 4 are anodized and covered with an anodic oxide film. Tartaric acid or oxalic acid, for example, is used in preparing the electrolytic solution 2. More specifically, the electrolytic solution 2 is prepared by adding six times diluted aqueous ammonia to a 3% solution of ethylene glycol tartrate to adjust its pH to 7.

FIG. 5 is a diagram representing changes over the time of the voltage applied to the substrate 3 and of the current that flows during an anodization process conducted in an anodic oxidization system shown in FIG. 4. After the power source 6 has begun to apply the voltage, the current is kept constant for a specified time period t1. This time period t1 is referred to as the constant-current period in which the voltage is gradually increased. More particularly, the system is controlled such that a constant current of 20 mA flows through each wafer and the voltage is gradually increased from 0 V to a maximum level of about 100 V. Even after the constant-current period t1 has elapsed, the anodization process is further carried out while maintaining the voltage at about 100 V. The current flowing from the substrate 3 to the electrode plate 5 gradually decreases during this period, and the anodization process is finished when the current has decreased to a predefined level after a specified time period t2, or the constant-voltage period. As stated above, the anodization process involves the constant-current period t1 and the constant-voltage period t2.

Generally, a large number of TFTs are provided in a peripheral circuit for driving a liquid crystal display (LCD). The peripheral circuit of this kind often employs TFTs connected in series or having a multigate structure. In such cases, the TFTs whose gate electrodes are formed of aluminum and covered with an anodic oxide film tend to produce a problem related to the anodic oxidization method.

FIG. 7 is a top view of TFT elements formed on an insulating substrate 20. A crystalline material such as polycrystalline silicon is deposited on the insulating substrate 20 which is made of silica glass, for instance. Then, a polycrystalline silicon island area (semiconductor island area) 11 of a specified shape on which a TFT is formed is created by a photolithographic process. After the formation of the semiconductor island area 11, the TFT is formed within the semiconductor island area 11 while a current supply line 7 and gate connecting lines 8a, 8b, 8c are formed outside the semiconductor island area 11.

During the anodization process, the current supply line 7 is connected to the individual gate connecting lines 8a, 8b and 8c so that currents flow to gate electrodes G1 and G2 connected to the gate connecting lines 8a, 8b and 8c. After the anodization process, the gate connecting lines 8a, 8b and 8c are cut at portions 9a, 9b and 9c shown by broken lines in FIG. 7 to thereby complete the desired TFT elements. The anodizing currents flow from the current supply line 7 to the gate electrodes G1 and G2 through the gate connecting lines 8a, 8b and 8c. In the TFT element and conductor pattern shown in FIG. 7, the anodizing currents supplied to the gate electrodes G1 and G2 which are formed on the same semiconductor island area 11 flow through different paths. Accordingly, a potential difference occurs between the gate electrodes G1 and G2, for instance, due to potential drops caused by the electric resistance of aluminum of which the gate connecting lines 8a, 8b and 8c are formed. FIG. 8 is a sectional diagram of the TFT circuit of FIG. 7 particularly showing its structure around the gate electrodes G1 and G2. When the potential difference occurs between the gate electrodes G1 and G2, the potential of the gate electrode G1 exceeding the potential of the gate electrode G2, for instance, a current I1 flows from the gate electrode G1 to the gate electrode G2 through a gate insulating layer 10 and the polycrystalline silicon semiconductor island area 11 as shown by a thick line with arrow in FIG. 8. Needless to say, there occurs a current I2 flowing from the gate electrodes G1 and G2 through the semiconductor island area 11. Since the additional current I1 flows through a region M2 between the two neighboring gate electrodes G1 and G2 running parallel to each other, the crystallinity of the semiconductor island area 11 in this region deteriorates. On the contrary, the current I2 flowing through a region M2 shown in FIGS. 7 and 8 is suppressed to a proper level so that the crystallinity of this region is improved. Deterioration of the crystallinity due to the excessive leakage current caused by the potential difference between the gate electrodes becomes more apparent when the distance between the gate electrodes becomes 2 to 3 micrometers or less. It is possible to easily detect such deterioration of the crystallinity due to the excessive current flowing through a bulk semiconductor layer of the TFT circuit as a result of the potential difference produced between the gate electrodes by measuring Raman spectra. FIG. 9 is a diagram showing the Raman spectra of the semiconductor layer measured before and after anodic oxidization in the TFT circuit configured as shown in FIG. 7.

Referring to FIG. 9, “Int” shows the spectrum of the semiconductor layer taken before anodic oxidization while “M1” and “M2” represent the spectra of regions M1 and M2 shown in FIG. 7, respectively, taken after anodic oxidization. FIG. 9 shows that the crystallinity of the region M1 is improved as its spectrum is shifted to the left, or toward the Raman peak of the crystal of Si(c—Si), whereas the crystallinity of the region M2 is deteriorated as its spectrum is shifted to the right. Deteriorated areas occasionally discolor when such deterioration of the crystallinity occurs. In the example shown in FIG. 7, the region M2 would discolor. FIG. 6 is a diagram showing the relationship between set voltages applied during the anodization process and film thickness of anodic oxide film. It can be seen from FIG. 6 that the thickness of the anodic oxide film increases almost linearly as the applied voltage is gradually increased up to a maximum level which is usually 80 to 100 V.

As thus far discussed, no particular attention was paid to the path of anodizing currents fed into each semiconductor island area when series-connected TFTs were anodized using the conventional anodic oxidization method although some consideration was given to ensure that the anodizing currents flow through individual TFT component elements. This used to produce a problem that, depending on the TFT circuit configuration, the lengths of anodizing current paths to individual gate electrodes would vary in the TFTs which should have uniform properties within the same semiconductor island area.

The distance between the individual gate electrodes within the TFTs would become even smaller if the tendency toward miniaturization of their component elements further advances. Especially when the distance between the gate electrodes becomes 2 to 3 micrometers or less, it becomes impossible to neglect minor potential differences produced between them as a result of the difference in path lengths of anodizing currents fed into the individual gate electrodes in each semiconductor island area during anodic oxidization. Leakage currents caused to flow from one gate electrode to another due to potential differences between them produce differences in anodizing conditions, and this gives rise to such problems as current leakage between the gate electrodes, partial anodization imperfections as well as peeling of the semiconductor layer in some cases.

### SUMMARY OF THE INVENTION

The present invention is intended to overcome the aforementioned problems of the prior art. Accordingly, it is an object of the invention to provide anodic oxidization methods which would not create a potential difference between neighboring gate electrodes formed in a common semiconductor island area during anodic oxidization.

In one aspect of the invention, an anodic oxidization method for anodizing areas including and surrounding a plurality of terminal conductor portions connected to a current supply line is such that the current supply line supplies current to the terminal conductor portions in a manner that the densities of current flowing through corresponding parts of any two parallel-running neighboring terminal conductor portions arranged in a semiconductor island area become substantially equal to each other.

In another aspect of the invention, an anodic oxidization method for anodizing areas including and surrounding a plurality of gate electrodes connected to a current supply line by respective gate connecting lines is such that the current supply line supplies current to the gate electrodes in a manner that the densities of current flowing through corresponding parts of any two parallelrunning neighboring gate electrodes arranged in a semiconductor island area become substantially equal to each other.

### BRIEF DESCRIPTION OF THE DRAWINGS

FIGS. 1A and 1B are diagrams showing examples of gate wiring employed during anodic oxidization according to an embodiment of the invention;

FIGS. 2A and 2B are diagrams showing how a plurality of TFTs are connected together;

FIGS. 3A and 3B are diagrams showing examples of gate wiring employed during anodic oxidization for creating circuits of FIGS. 2A and 2B, respectively, according to a conventional wiring method;

FIG. 4 is a diagram showing an example of an anodic oxidization method;

FIG. 5 is a diagram representing changes over the time of a supply voltage and a current during anodic oxidization;

FIG. 6 is a diagram showing the relationship between set voltages applied during an anodization process and the thickness of an anodic oxide film;

FIG. 7 is a top view showing how individual TFT elements are connected during anodic oxidization;

FIG. 8 is a sectional diagram showing a structure around gate electrodes of FIG. 7;

FIG. 9 is a diagram showing Raman spectra measured before and after anodic oxidization of a TFT circuit shown in FIG. 7;

FIG. 10 is a top view showing part of a peripheral circuit for driving a LCD; and

FIGS. 11A-11D are sectional diagrams taken along lines A-A of FIG. 10 showing manufacturing processes of the circuit.

### DESCRIPTION OF THE PREFERRED EMBODIMENT

The invention is now described in detail with reference to its preferred embodiment.

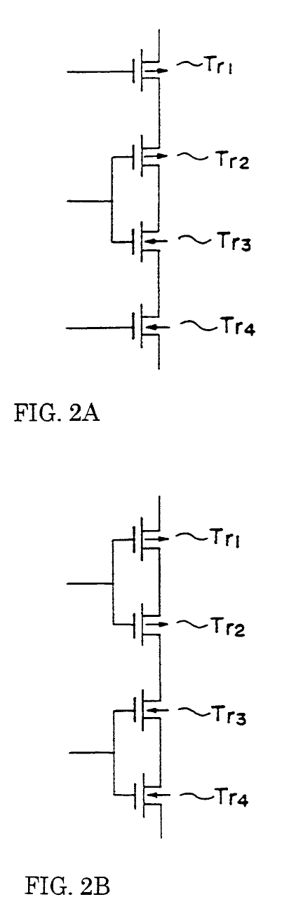

FIGS. 2A and 2B are diagrams showing exemplary TFT circuits in which a plurality of TFTs are connected together. Specifically, p-channel transistors Tr1 and Tr2 and n-channel transistors Tr3 and Tr4 are connected in series in the circuit of FIG. 2A, whereas multigate-type TFTs Tr1, Tr2 and Tr3, Tr4 are connected in series in the circuit of FIG. 2B.

In FIG. 2A, gates of the transistors Tr2 and Tr3 are connected with each other. In FIG. 2B, the transistors Tr1 and Tr2 constitute a multigate-type TFT as do the transistors Tr3 and Tr4 in a similar way.

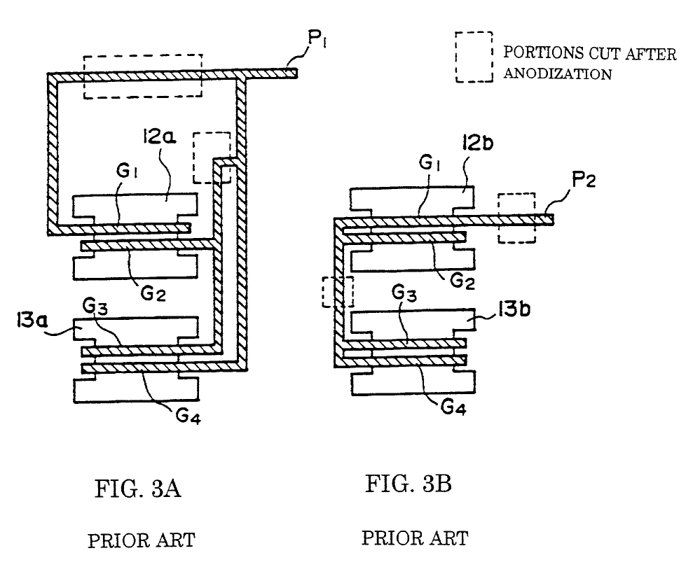

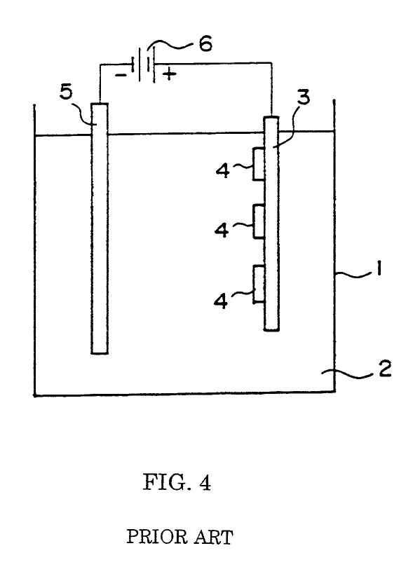

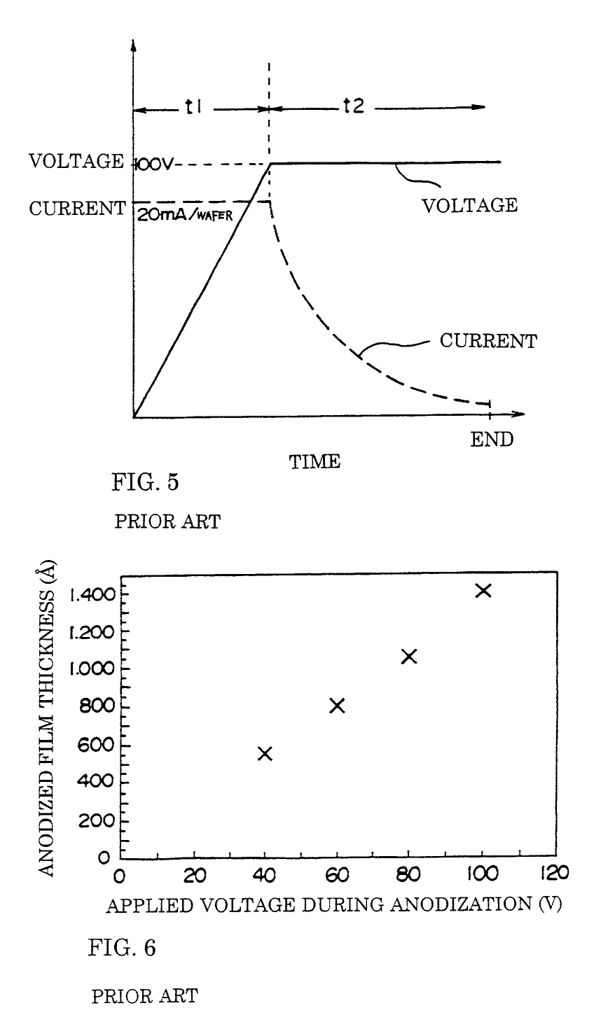

FIGS. 3A and 3B are diagrams showing examples of gate wiring employed during anodic oxidization for creating the circuits of FIGS. 2A and 2B, respectively, according to a conventional wiring method. Referring to FIG. 3A, transistors Tr and Tr2 are formed on a common semiconductor island area 12a while transistors Tr3 and Tr4 are formed on a common semiconductor island area 13a. Likewise, transistors Tr1 and Tr2 are formed on a common semiconductor island area 12b while transistors Tr3 and Tr4 are formed on a common semiconductor island area 13b in FIG. 3B.

An anodizing current is fed from a current supply point P1 during anodic oxidization in the gate wiring shown in FIG. 3A, while an anodizing current is fed from a current supply point P2 during anodic oxidization in the gate wiring shown in FIG. 3B.

Upon completion of the anodization process, gate connecting lines are cut at portions shown by broken lines in FIGS. 3A and 3B by etching and removing conductor in those portions by a photolithographic process, for example, to produce the TFT circuits shown in FIGS. 2A and 2B, respectively. Discussion below focuses on paths of currents flowing through individual gate electrodes G1-G4 and gate connecting lines during the anodization process.

It can be seen from a comparison of distances from the current supply point P1 to the middle points of the individual gate electrodes G1-G4 of FIG. 3A that potentials at the middle points of the gate electrodes G1-G4 differ from one another due to differences in the resistances of the gate electrodes G1-G4 and the gate connecting lines. Accordingly, a potential difference occurs between the two neighboring gate electrodes G1 and G2, for instance, which run parallel to each other in the same semiconductor island area 12a. Similarly, a potential difference occurs between the two neighboring gate electrodes G3 and G4 which run parallel to each other in the same semiconductor island area 13a due to the difference in current path lengths. A similar situation exists in the TFT circuit of FIG. 3B as well. Specifically, potential differences occur between neighboring gate electrodes G1 and G2 running parallel to each other in the same semiconductor island area 12b, and between neighboring gate electrodes G3 and G4 running parallel to each other in the same semiconductor island area 13b, due to differences in current path lengths from the current supply point P2 to the individual gate electrodes G1-G4 of FIG. 3B. As previously mentioned, a leakage current flows from one gate electrode to another through a gate oxide film and a semiconductor layer as a result of the potential differences, and this would cause such failures as crystal defects, anodic oxide film imperfections and peeling of the semiconductor layer.

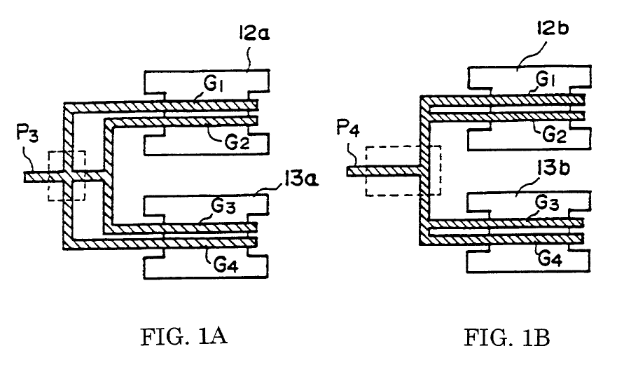

FIGS. 1A and 1B are diagrams showing examples of gate wiring according to the embodiment of the invention.

FIGS. 1A and 1B correspond to FIGS. 2A and 2B, respectively. In FIGS. 1A and 1B, P3 and P4 designate current supply points of respective TFT circuits, in which gate connecting lines are cut at portions shown by broken lines. As is apparent from FIGS. 1A and 1B, paths of currents flowing from the current supply points P3 and P4 to individual gate electrodes G1-G4 have approximately the same length so that the individual anodizing current paths have the same resistance. Accordingly, potential drops along the individual anodizing current paths are equal to each other in either of the TFT circuits and, therefore, no potential difference occurs between the neighboring electrodes. Unlike the conventional gate wiring shown in FIGS. 3A and 3B, no leakage current due to gate-to-gate potential differences flows between the neighboring gate electrodes in one of semiconductor island areas 12a, 13a, 12b, 13b of FIGS. 1A and 1B during anodic oxidization. Thus, the gate wiring shown in FIGS. 1A and 1B would not develop the earlier-mentioned problems, such as crystal defects and partial anodization imperfections in anodic oxide films.

The gate electrodes G1-G4 and the gate connecting lines have a common conductor width in the embodiment shown in FIGS. 1A and 1B. Therefore, the gate wiring should be patterned such that path lengths from the current supply point P3 (P4) to the middle points of the individual gate electrodes G1-G4 (terminal conductor portions) become approximately equal to each other to ensure that no potential difference occurs between the neighboring gate electrodes in a semiconductor island area when anodizing currents are supplied thereto.

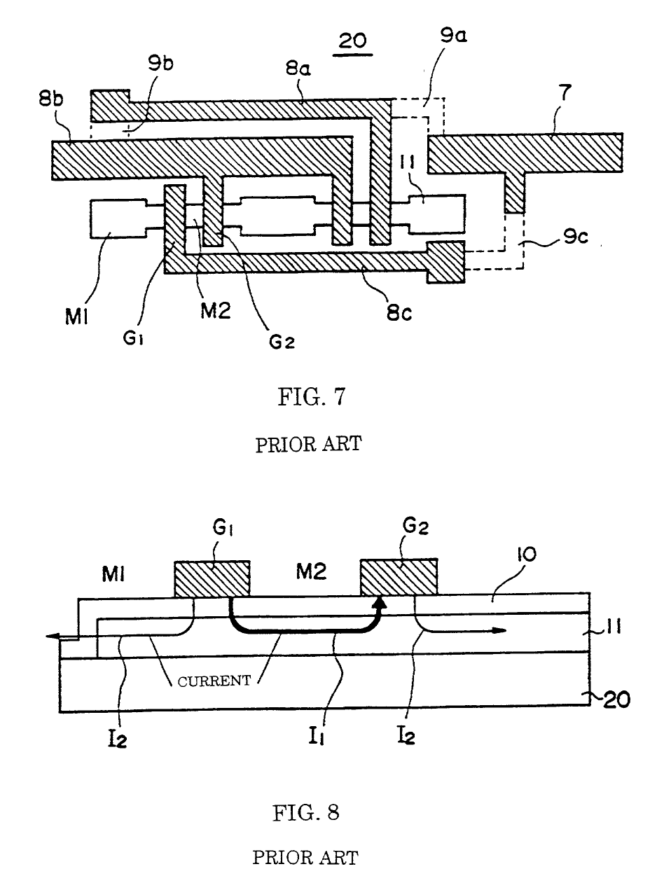

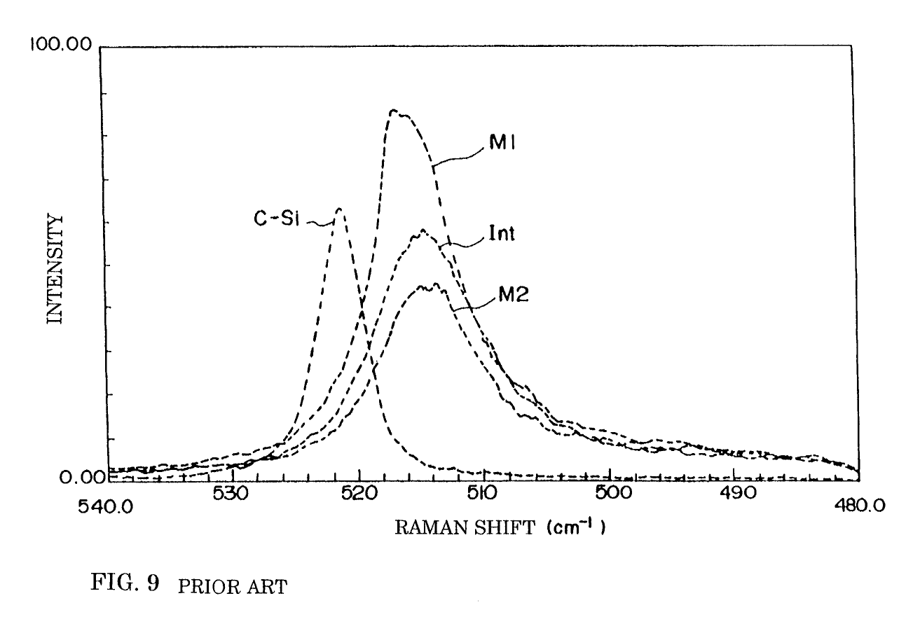

In some cases, however, the conductor width would vary within a single TFT circuit like the example shown in FIG. 7, in which the current supply line 7, the gate connecting lines 8a, 8b, 8c and the gate electrodes G1, G2 have different widths. In such cases, it is not possible to zero the gate-to-gate potential difference by making path lengths from a current supply point on a current supply line to the middle points of individual gate electrodes equal to each other. It would be necessary to determine wiring paths which make the potentials of two neighboring gate electrodes in each semiconductor island area equal to each other taking account of the widths of the individual gate connecting lines in these cases. It is generally difficult to calculate potential drops along individual current paths when the widths of the current supply line, gate connecting lines and gate electrodes are varied in different ways. Accordingly, a preferable, and practical, approach is to define standard conductor widths, such as 100 micrometers for current supply lines, 20 micrometers for gate connecting lines and 10 micrometers for gate electrodes, and then design the TFT circuit so that the effective lengths of individual current paths determined by the actual conductor lengths and the conductor widths become equal to each other.

While the foregoing discussion of the embodiment shown in FIGS. 1A and 1B has dealt with circuit configurations containing two gate electrodes (terminal conductor portions), it is preferable to employ a conductor layout which will not create a potential difference between neighboring gate electrodes in a semiconductor island area when more than two parallel gate electrodes exist.

A method of manufacturing a TFT circuit employing the anodic oxidization method of the invention is now described.

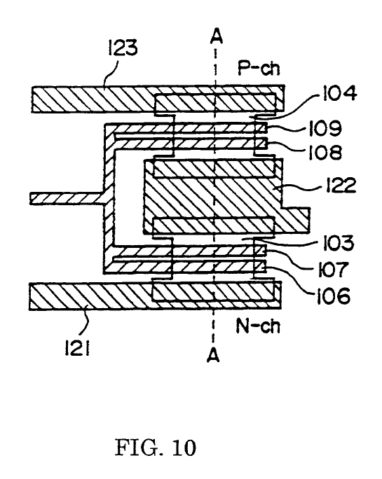

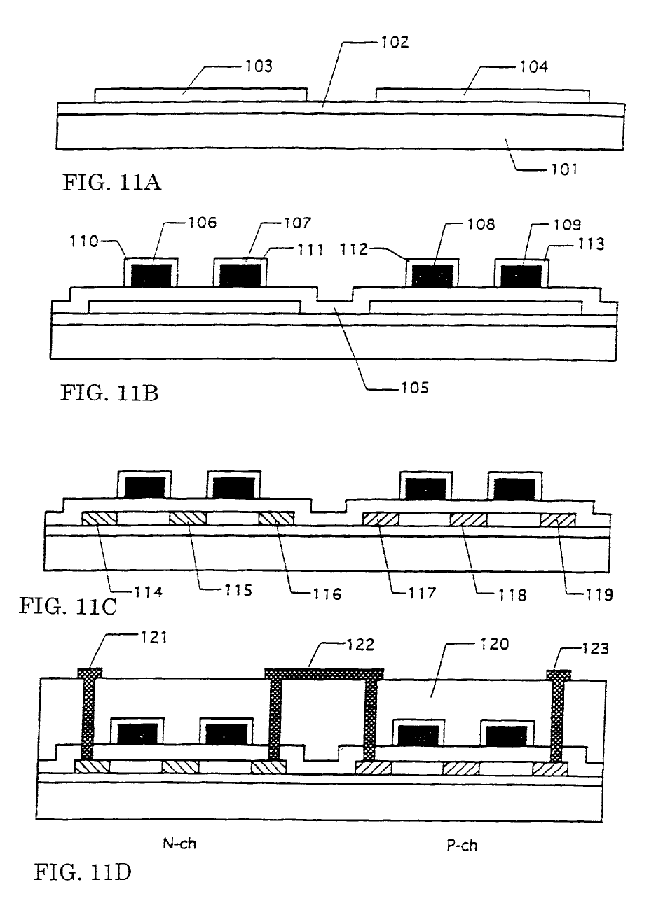

FIG. 10 is a top view showing part of a peripheral circuit for driving an LCD. FIGS. 11A-11D are sectional diagrams taken along lines A-A of FIG. 10 showing manufacturing processes of the circuit.

First, an underlying layer 102 is formed on an insulating substrate 101 which is made of glass or quartz, for instance, by depositing a silicon oxide film thereupon to a thickness of 1500 to 2500 Å as shown in FIG. 11A.

Next, an amorphous silicon film is formed on top of the underlying layer 102 to a thickness of 500 to 600 Å and this amorphous silicon film is crystallized by using a conventional process, such as heating or laser annealing. The crystallized amorphous silicon film is patterned into a desired layout, creating semiconductor island areas 103 and 104.

Then, a silicon oxide film is deposited to a thickness of 1000 to 1500 Å to form a gate insulating layer 105 covering the semiconductor island areas 103 and 104. Subsequently, a layer of aluminum is deposited onto the gate insulating layer 105 to a thickness of 4000 Å by using the sputtering method. Preferably, the aluminum layer contains a small amount of scandium (Sc), titanium (Ti) or silicon (Si) for preventing formation of hillocks and whiskers in later processes. It is also possible to use tantalum instead of aluminum. The aluminum layer is patterned to form gate electrodes 106, 107, 108 and 109. Outer surfaces of the gate electrodes 106-109 are then anodized to produce anodic oxide films 110, 111, 112 and 113. An electrolytic solution used in this anodization process is prepared by adding six times diluted aqueous ammonia to a 3% solution of ethylene glycol tartrate to adjust its pH to 6.92.

Current and voltage conditions applied to the anodization process are as follows. A current of 20 mA per wafer is caused to flow during a constant-current period while increasing the voltage up to 100 V at a rate of 5 to 10 V per minute. The voltage is then maintained at 100 V for a constant-voltage period of 30 minutes.

Since gate connecting lines are formed as shown in FIG. 10 in this anodization process to prevent the occurrence of potential differences between the gate electrodes in the same semiconductor island areas, no electric current flows through the semiconductor island areas. Accordingly, the anodization process does not destroy the crystallinity of the semiconductor island areas or produce any anodization defects.

Subsequently, source and drain regions are created by the ion implantation or ion doping method, using the gate electrodes 106-109 covered by the anodic oxide films 110-113 as masks. More particularly, p-type source and drain regions 117-119 are formed by injecting boron (B) into the semiconductor island area 104 with the semiconductor island area 103 masked. Likewise, n-type source and drain regions 114-116 are formed by injecting phosphorus (P) into the semiconductor island area 103 with the semiconductor island area 104 masked. In this process, offset regions are created immediately below side walls of the anodic oxide films 110-113 covering the gate electrodes 106-109. An n-channel TFT is created in the semiconductor island area 103 while a p-channel TFT is created in the semiconductor island area 104 in the above-described manner.

An interlayer dielectric film 120 covering the entire substrate surface is then formed as shown in FIG. 1D. The interlayer dielectric film 120 may be formed of a single-layer film of silicon nitride or silicon oxide, or of a multilayer film thereof.

Finally, contact holes are made in the interlayer dielectric film 120 and source and drain electrodes 121-123 are formed to complete the TFT circuit as shown in FIG. 1D.

In the light of the above according to this invention, no leakage current flows from one gate electrode to another in the anodic oxidization methods of the invention because anodizing currents are supplied in such a way that no potential difference occurs between any two neighboring gate electrodes (terminal conductor portions) during anodic oxidization as a result of differences in current path lengths. It is therefore possible to prevent crystal defects and partial anodization imperfections which could potentially be caused by leakage currents. Accordingly, the invention provides such advantage that anodic oxidization technology can be effectively utilized in miniaturized TFT circuits.

What is claimed is:

1. An anodic oxidization method for anodizing areas including and surrounding a plurality of terminal conductor portions connected to a current supply line, in which said current supply line supplies current to said terminal conductor portions in a manner that the densities of current flowing through corresponding parts of any two parallel-running neighboring terminal conductor portions arranged in a semiconductor island area become substantially equal to each other.

2. An anodic oxidization method for anodizing areas including and surrounding a plurality of gate electrodes connected to a current supply line by respective gate connecting lines, in which said current supply line supplies current to said gate electrodes in a manner that the densities of current flowing through corresponding parts of any two parallel-running neighboring gate electrodes arranged in a semiconductor island area become substantially equal to each other.

3. A method comprising the steps of:
providing a semiconductor island over an insulating surface;
forming at least two gate electrodes arranged in parallel over said semiconductor island with a gate insulating film therebetween, each of said gate electrodes connected to a current supply line by respective gate connecting line; and
anodizing surfaces of said two gate electrodes by supplying current to a current supply point in said current supply line,
wherein no potential difference occurs between said two gate electrodes.

4. The method according to claim 3 wherein current paths from said current supply point to each middle point of said two gate electrodes become equal length.
